(19) United States
(12) Patent Application Publication
(10) Pub. No.: US 2016/0351670 A1
(43) Pub. Date: Dec. 1, 2016

(54) THIN FILM TRANSISTOR STRUCTURE AND MANUFACTURING METHOD THEREOF, ARRAY SUBSTRATE, AND MASK

(71) Applicants: BOE TECHNOLOGY GROUP CO., LTD., Beijing (CN); CHONGQING BOE OPTOELECTRONICS TECHNOLOGY CO., LTD., Beibei, Chongqing (CN)

(72) Inventors: Zhe LI, Beijing (CN); Fei SHANG, Beijing (CN); Haijun QIU, Beijing (CN)

(21) Appl. No.: 14/892,091

(22) PCT Filed: Apr. 20, 2015
(86) PCT No.: PCT/CN2015/076957

§ 371 Date: Nov. 18, 2015

(30) Foreign Application Priority Data
Jan. 21, 2015 (CN) 201510030108.X

(51) Int. Cl. H01L 29/417; H01L 27/12; H01L 29/40; H01L 29/786

(52) U.S. Cl. CPC H01L 29/41733; H01L 29/786; H01L 27/124; H01L 29/401

(57) ABSTRACT

A thin film transistor structure and a manufacturing method thereof, an array substrate, and a mask are provided. The thin film transistor structure includes: a source electrode and a drain electrode disposed in a same layer, wherein, the source electrode includes a first bending portion, and the drain electrode includes a second bending portion, the first bending portion and the second bending portion are nested and spaced from each other.

### TECHNICAL FIELD

Embodiments of the present disclosure relate to a thin film transistor structure and a manufacturing method thereof, an array substrate, and a mask.

### BACKGROUND

With development of a display technology, people demand higher and higher on various display performance. In parameters that influence the display performance of the thin film transistor, much attention has been paid to on state current. Improving the on state current enables a charging rate of the thin film transistor structure to improve. Wherein, the on state current is calculated by a formula

$${I}_{on} = \frac{1}{2} \times \frac{W}{L} \times {C}_{ox} \times u \times {( {V}_{gs} - {V}_{th} )}^{2} ,$$

where Iₒₙ represents the on state current,

$$\frac{W}{L}$$

represents a channel width to length ratio, Cₒₓ represents capacitance between a gate line layer and an active layer by per unit area, u represents an electron mobility, V_{gs} represents a difference between an applied voltage and a voltage after charging, and Vₜₕ represents a voltage threshold.

### SUMMARY

An embodiment of the present disclosure provides a thin film transistor structure, comprising: a source electrode and a drain electrode disposed in a same layer, wherein, the source electrode includes a first bending portion, and the drain electrode includes a second bending portion, the first bending portion and the second bending portion are nested and spaced from each other

Another embodiment of the present disclosure provides an array substrate, comprising the above described thin film transistor structure

Still another embodiment of the present disclosure provides a mask comprising a mask body including a transparent region and an non-transparent region, the non-transparent region including a first non-transparent region for covering a source electrode which includes a first bending portion and a second non-transparent region for covering a drain electrode which includes a second bending portion, the first bending portion and the second bending portion being nested and spaced from each other.

Yet another embodiment of the present disclosure provides a manufacturing method of a thin film transistor structure, comprising:

forming an active layer; and

patterning the active layer to form a pattern which includes a source electrode and a drain electrode by a patterning process, wherein the source electrode includes a first bending portion, and the drain electrode includes a second bending portion, the first bending portion and the second bending portion are nested and spaced from each other.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic diagram of a thin film transistor structure in a related art;

FIG. 2 is a schematic diagram of a thin film transistor structure provided by an embodiment of the disclosure;

FIG. 3A is a partially enlarged schematic diagram of a source electrode in FIG. 2;

FIG. 3B is a partially enlarged schematic diagram of a drain electrode in FIG. 2;

FIG. 3C is a partially enlarged schematic diagram of the source electrode and the drain electrode in FIG. 2;

FIG. 4 is a schematic diagram of another thin film transistor structure provided by an embodiment of the disclosure;

FIG. 5 is a partially enlarged schematic diagram of the source electrode and the drain electrode in FIG. 4;

FIG. 6 is a schematic diagram of a mask for forming the source electrode and the drain electrode in FIG. 4;

FIG. 7 is a schematic diagram of a mask for forming the source electrode and the drain electrode in FIG. 5.

### DETAILED DESCRIPTION

The technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

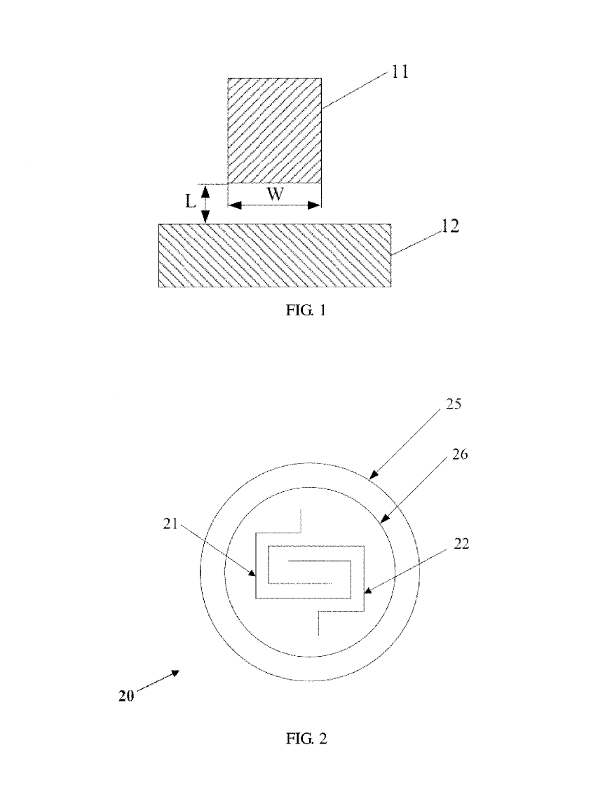

By increasing the channel width to length ratio (Width/Length, referred to as W/L), the on state current Iₒₙ can be increased. Referring to FIG. 1, in the thin film transistor structure of a related art, L represents a distance between a source electrode 11 and a drain electrode 12, and W represents a relative width, perpendicular to L, between the source electrode 11 and the drain electrode 12. However, due to restrictions of the thin film transistor structure shown in FIG. 1, the on state current cannot be sufficiently increased by increasing the channel width to length ratio, such that the charging rate of the thin film transistor structure is still relatively low.

The embodiments of the present disclosure provide a thin film transistor structure and a manufacturing method thereof, an array substrate, and a mask, which can solve the problem of relatively low charging rate of the thin film transistor structure.

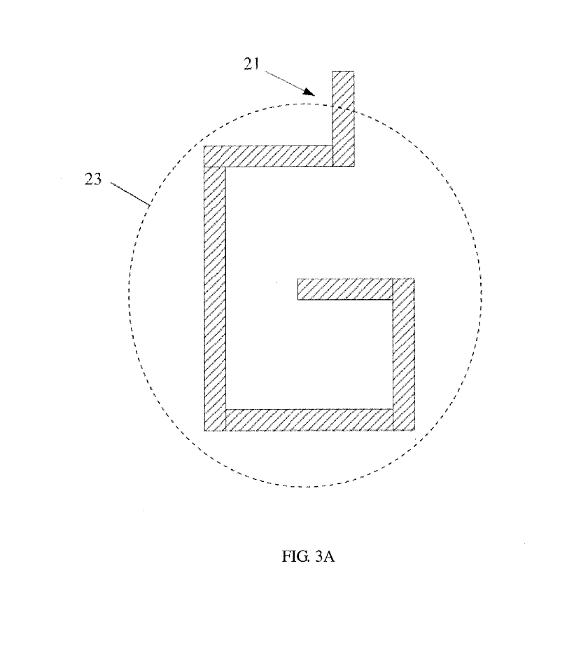

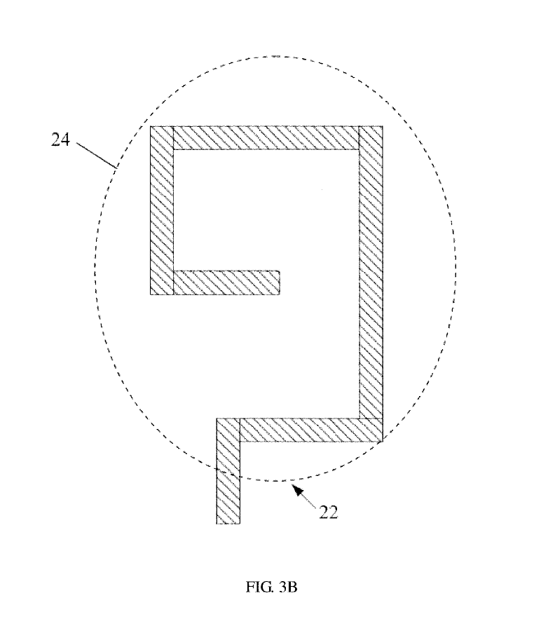

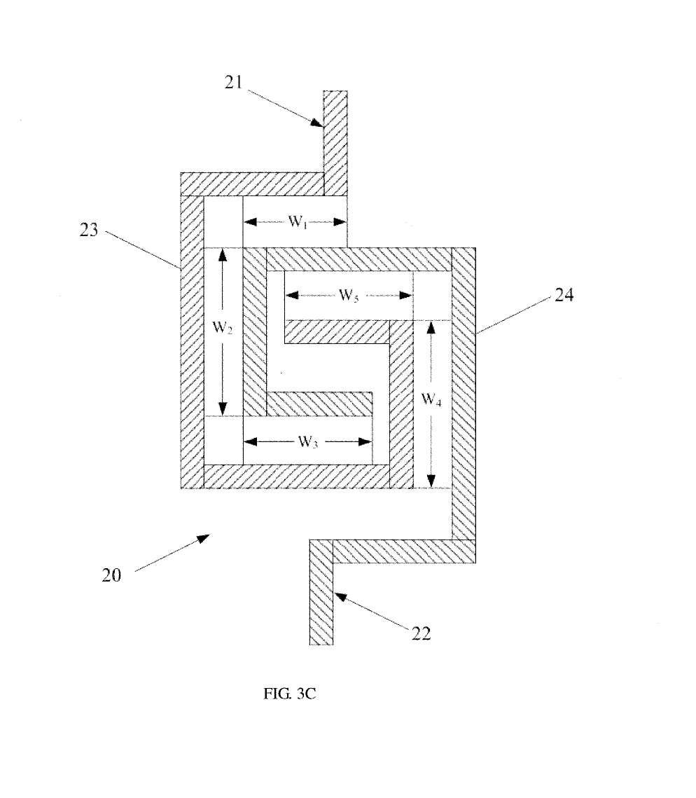

Referring to FIGS. 3A-3C and FIG. 5, a thin film transistor structure 20 provided by an embodiment of the disclosure comprises: a source electrode 21 and a drain electrode 22 disposed in a same layer, wherein, the source electrode 21 includes a first bending portion 23 in non-linear configuration (refer to a dotted oval shown in FIG. 3A), and the drain electrode 22 includes a second bending portion 24 in continuous non-linear configuration (refer to a dotted oval shown in FIG. 3B). The first bending portion 23 and the second bending portion 24 are configured to be nested each other and spaced from each other. In the embodiments shown in FIGS. 3A-3C and FIG. 5, the first bending portion 23 and the second bending portion 24 are respectively configured to have a plurality of corners. A projection of the first bending portion 23 on the second bending portion 24 covers at least part of the second bending portion 24. In an example, the distance L between the first bending portion 23 and the second bending portion 24 is constant.

In the thin film transistor structure provided by an embodiment of the disclosure, the source electrode 21 and the drain electrode 22 respectively include a first bending portion and a second bending portion which are nested and spaced from each other. A projection of the bending portion of the source electrode 21 on the bending portion of the drain electrode 22 covers at least part of the bending portion of the drain electrode 22. Referring to FIG. 3C, the relative width W between the source electrode 21 and the drain electrode 22 equals to a sum of W1, W2, W3, W4 and W5. Compared with the relative width W between the source electrode 21 and the drain electrode 22 of the thin film transistor structure in the related art as shown in FIG. 1, the thin film transistor structure provided by the embodiment of the disclosure can greatly enlarge the relative width W between the source electrode 21 and the drain electrode 22, thus increasing the channel width to length ratio W/L. Therefore, the on state current and the charging rate of the thin film transistor structure 20 can be correspondingly increased.

In order to further enlarge the relative width W between the source electrode 21 and the drain electrode 22, referring to FIGS. 3A-3C, both the first bending portion 23 and the second bending portion 24 are spirals.

Optionally, the first bending portion 23 and the second bending portion 24 are in any shape of: a square spiral, an arbitrary polygon spiral, a circular spiral, and an oval spiral.

In order to further enlarge the relative width W between the source electrode 21 and the drain electrode 22, referring to FIG. 5, both the first bending portion 23 and the second bending portion 24 are serrations.

Optionally, the first bending portion 23 and the second bending portion 24 are in any shape of: a square serration, a triangle serration, and a circular arc serration.

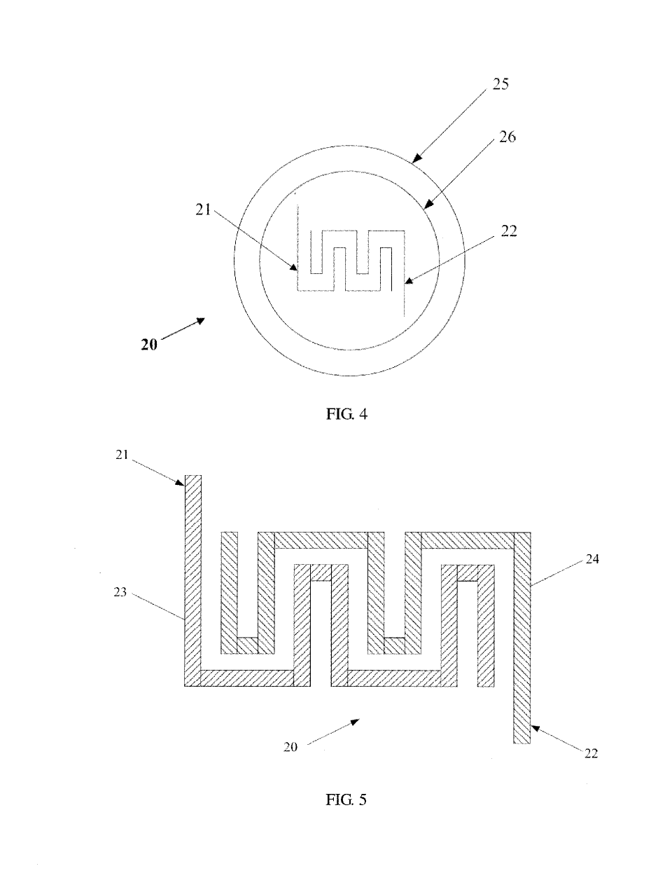

For example, referring to FIG. 2 and FIG. 4, the thin film transistor structure 20 further comprises a gate layer 25, and an active layer 26 disposed on the gate layer 25. The source electrode 21 and the drain electrode 22 are disposed on the active layer 26. Both the gate layer 25 and the active layer 26 being of circular structure.

An embodiment of the present disclosure further provides an array substrate, comprising: the above described thin film transistor structure 20.

In the array substrate provided by the embodiment of the present disclosure, since the source electrode and the drain electrode respectively include the bending portions, and the two bending portions are nested and spaced from each other, the relative width W between the source electrode and the drain electrode can be enlarged, i.e., the channel width to length ratio W/L is increased, which can increase the corresponding on state current and further increase the charging rate of the thin film transistor structure.

An embodiment of the present disclosure further provides a display device, comprising the array substrate described above. The display device of the embodiment of the present disclosure can be: liquid crystal display panel, E-paper, organic light-emitting diode panel (referred to as OLED panel), mobile phone, tablet computer, television, monitor, laptop computer, digital photo frame, navigator, or any product or part having a display function.

In the display device provided by the embodiment of the present disclosure, since the source electrode and the drain electrode respectively include the bending portions, and the two bending portions are nested and spaced from each other, the relative width W between the source electrode and the drain electrode can be enlarged, i.e., the channel width to length ratio W/L is increased, which can increase the corresponding on state current and further increase the charging rate of the thin film transistor structure.

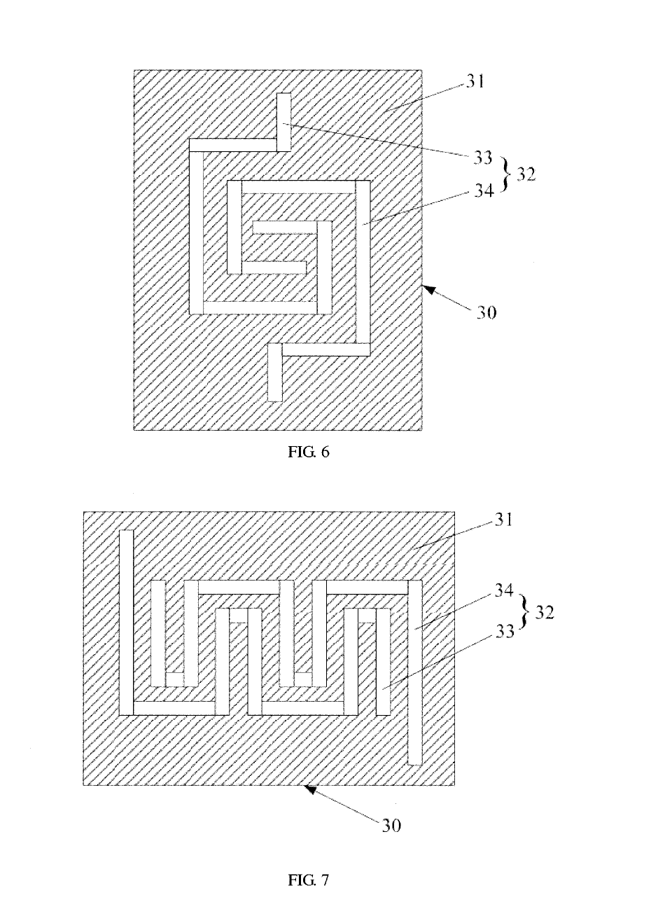

An embodiment of the present disclosure further provides a mask, comprising a mask body 30. Referring to FIG. 6 and FIG. 7, the mask body 30 includes a transparent region 31 and an non-transparent region 32. The non-transparent region includes a first non-transparent region 33 for forming a source electrode 21 which includes a first bending portion 23 and a second non-transparent region 34 forming a drain electrode 22 which includes a second bending portion 24. The first bending portion 23 and the second bending portion 24 are nested and spaced from each other. A projection of the first bending portion 23 on the second bending portion 24 covers at least part of the second bending portion 24.

The source electrode 21 and the drain electrode 22 formed by using the mask provided by the embodiment of the disclosure each include the bending portions, the two bending portions being nested and spaced from each other. The projection of the bending portion of the source electrode 21 on the bending portion of the drain electrode 22 covers at least part of the bending portion of the drain electrode 22. Thus, the relative width W between the source electrode 21 and the drain electrode 22 can be greatly enlarged, i.e., the channel width to length ratio W/L, the corresponding on state current and the charging rate of the thin film transistor structure 20 can be increased.

An embodiment of the present disclosure further provides a manufacturing method of a thin film transistor structure, for use in improving the charging rate of the thin film transistor structure, the method comprising:

801: forming an active layer.

802: patterning the active layer to form a pattern which includes a source electrode and a drain electrode by a patterning process, wherein the source electrode includes a first bending portion, and the drain electrode includes a second bending portion, the first bending portion and the second bending portion are nested and spaced from each other, and a projection of the first bending portion on the second bending portion covers at least part of the second bending portion.

Wherein, the patterning process in step 802 can be a conventional patterning process, which may include, for example, photoresist coating, exposure, development, etching and photoresist stripping.

In the manufacturing method of a thin film transistor structure provided by the embodiment of the present disclosure, the source electrode and the drain electrode each include the bending portions, the two bending portions being nested and spaced from each other, and the projection of the bending portion of the source electrode on the bending portion of the drain electrode covers at least part of the bending portion of the drain electrode. Therefore, the relative width W between the source electrode and the drain electrode can be enlarged, i.e., the channel width to length ratio W/L is increased, which can increase the corresponding on state current and further increase the charging rate of the thin film transistor structure.

Optionally, both the first bending portion and the second bending portion are spirals. Wherein, the first bending portion and the second bending portion are in any shape of: a square spiral, an arbitrary polygon spiral, a circular spiral, and an oval spiral. The first bending portion in spiral shape and the second bending portion in spiral shape are nested and spaced from each other and disposed on the active layer, which thus can further enlarge the relative width W between the source electrode and the drain electrode and further increase the charging rate of the thin film transistor structure.

Optionally, both the first bending portion and the second bending portion are serrations. Wherein, the first bending portion and the second bending portion are in any shape of: a square serration, a triangle serration, and a circular arc serration. The first bending portion in serration shape and the second bending portion in serration shape are nested and spaced from each other and disposed on the active layer, which thus can further enlarge the relative width W between the source electrode and the drain electrode and further increase the charging rate of the thin film transistor structure.

The array substrate and the display device provided by the embodiments of the disclosure can possess advantages of the thin film transistor structure 20 provided by the above embodiments of the disclosure; and as for implementation of their structures, please refer to the description on the thin film transistor structure 20 in the above embodiments, which will not be repeated here. The thin film transistor structure and the manufacturing method thereof, the array substrate, and the mask provided by the embodiments of the disclosure may be applicable in achieving the display function, but is not limited thereto.

In the description of the above implementation modes, the specific features, structures, materials, or characters can be combined in a suitable manner in any one or more of the embodiments or examples.

Based on the above description, the embodiments of the disclosure can at least provide the structures and methods as follows:

(1) A thin film transistor structure, comprising: a source electrode and a drain electrode disposed in a same layer, wherein, the source electrode includes a first bending portion, and the drain electrode includes a second bending portion, the first bending portion and the second bending portion being nested and spaced from each other.

(2) The thin film transistor structure according to (1), wherein, both the first bending portion and the second bending portion are spirals.

(3) The thin film transistor structure according to (2), wherein, the first bending portion and the second bending portion are in any shape of: a square spiral, an arbitrary polygon spiral, a circular spiral, and an oval spiral.

(4) The thin film transistor structure according to (1), wherein, both the first bending portion and the second bending portion are serrations.

(5) The thin film transistor structure according to (4), wherein, the first bending portion and the second bending portion are in any shape of: a square serration, a triangle serration, and a circular arc serration.

(6) The thin film transistor structure according to any one of (1) to (5), wherein, the thin film transistor structure further comprises a gate layer, and an active layer disposed on the gate layer, and the source electrode and the drain electrode are disposed on the active layer, both the gate layer and the active layer are of circular structure.

(7) An array substrate, comprising the thin film transistor structure according to any one of (1) to (6).

(8) A mask, comprising a mask body including a transparent region and an non-transparent region, the non-transparent region including a first non-transparent region for covering a source electrode which includes a first bending portion and a second non-transparent region for covering a drain electrode which includes a second bending portion, the first bending portion and the second bending portion being nested and spaced from each other.

(9) A manufacturing method of a thin film transistor structure, comprising:

forming an active layer; and

patterning the active layer to form a pattern which includes a source electrode and a drain electrode by a patterning process, wherein the source electrode includes a first bending portion, and the drain electrode includes a second bending portion, the first bending portion and the second bending portion being nested and spaced from each other.

(10) The manufacturing method according to (9), wherein, both the first bending portion and the second bending portion are spirals; the first bending portion and the second bending portion are in any shape of: a square spiral, an arbitrary polygon spiral, a circular spiral, and an oval spiral.

(11) The manufacturing method according to (9), wherein, both the first bending portion and the second bending portion are serrations; the first bending portion and the second bending portion are in any shape of: a square serration, a triangle serration, and a circular arc serration.

It is obvious for the skilled in the art that although the disclosure has been explained in detail in connection with general descriptions and specific embodiments, certain modifications or improvements can be made thereto on the basis of the present disclosure. Therefore, these modifications or improvements without departing from the spirit and scope of the present disclosure belong to the scope sought for protection in the present disclosure.

The present application claims priority of Chinese Patent Application No. 201510030108.X filed on Jan. 21, 2015, the disclosure of which is incorporated herein by reference in its entirety as part of the present application.

1. A thin film transistor structure, comprising: a source electrode and a drain electrode disposed in a same layer, wherein, the source electrode includes a first bending portion, and the drain electrode includes a second bending portion, the first bending portion and the second bending portion are nested and spaced from each other.

2. The thin film transistor structure according to claim 1, wherein, both the first bending portion and the second bending portion are spirals.

3. The thin film transistor structure according to claim 2, wherein, the first bending portion and the second bending portion are in any shape of: a square spiral, an arbitrary polygon spiral, a circular spiral, and an oval spiral.

4. The thin film transistor structure according to claim 1, wherein, both the first bending portion and the second bending portion are serrations.

5. The thin film transistor structure according to claim 4, wherein, the first bending portion and the second bending portion are in any shape of: a square serration, a triangle serration, and a circular arc serration.

6. The thin film transistor structure according to claim 1, wherein, the thin film transistor structure further comprises a gate layer and an active layer disposed on the gate layer, and the source electrode and the drain electrode are disposed on the active layer, both the gate layer and the active layer are of circular structure.

7. An array substrate, comprising: the thin film transistor structure according to claim 1.

8. A mask, comprising a mask body including a transparent region and an non-transparent region, the non-transparent region including a first non-transparent region for covering a source electrode which includes a first bending portion and a second non-transparent region for covering a drain electrode which includes a second bending portion, the first bending portion and the second bending portion being nested and spaced from each other.

9. A manufacturing method of a thin film transistor structure, comprising:
forming an active layer; and
patterning the active layer to form a pattern which includes a source electrode and a drain electrode by a patterning process, wherein the source electrode includes a first bending portion, and the drain electrode includes a second bending portion, the first bending portion and the second bending portion are nested and spaced from each other.

10. The manufacturing method according to claim 9, wherein, both the first bending portion and the second bending portion are spirals; the first bending portion and the second bending portion are in any shape of: a square spiral, an arbitrary polygon spiral, a circular spiral, and an oval spiral.

11. The manufacturing method according to claim 9, wherein, both the first bending portion and the second bending portion are serrations; the first bending portion and the second bending portion are in any shape of: a square serration, a triangle serration, and a circular arc serration.
